(19) United States
(12) Patent Application Publication
(10) Pub. No.: US 2010/0149778 A1
(43) Pub. Date: Jun. 17, 2010

(54) ENCLOSURE FOR ELECTRONIC DEVICE

(75) Inventors: CHIN-WEN YEH, Tu-Cheng (TW); ZHEN-NENG LIN, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (SHENZHEN) CO., LTD., Shenzhen City (CN); HON HAI PRECISION INDUSTRY CO., LTD., Tu-Cheng (TW)

(21) Appl. No.: 12/486,130

(22) Filed: Jun. 17, 2009

(30) Foreign Application Priority Data
Dec. 17, 2008 (CN) 200820303475.8

(51) Int. Cl. H05K 7/00

(52) U.S. Cl. 361/809

(57) ABSTRACT

An enclosure for electronic device includes a chassis, a power supply, and a cover. The chassis includes a bottom wall. A ring and a plurality of elastic pieces protrude from the bottom wall. The power supply includes a top side and bottom side. The bottom side defines a sliding groove. The top side defines a receiving groove. The power supply is located on the plurality of elastic pieces of the chassis with the ring positioned in the sliding groove. The cover includes a protrusion. The cover is mounted on the chassis. The protrusion is positioned in the receiving groove, and biases the power supply toward the plurality of elastic pieces.

### BACKGROUND

1. Technical Field

The present disclosure relates to electronic device enclosures, and particularly to an enclosure for readily and securely attaching a power supply therein.

2. Description of Related Art

Generally speaking, a power supply is necessarily assembled in a computer enclosure. The power supply is often directly attached to a rear panel of the computer enclosure by a plurality of screws. However, this requires extra tools such as screwdrivers in assembly or disassembly, which is unduly laborious and time-consuming. Additionally, it requires a longer assembly line, which lowers assembly efficiency. Furthermore, an unworkable work site will lead to paralysis of the whole assembly line.

Another conventional mounting way is to assemble a power supply to a bracket, and then attach the bracket together with the power supply to the computer enclosure. By this way, the power supply is assembled outside the assembly line, thereby avoiding the paralysis of the whole assembly line when an unworkable work site occurs. However, screws are still needed to fix the bracket to the computer enclosure. When maintaining or repairing the power supply, screwdrivers are needed to unscrew the screws to take the power supply off.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric and exploded view of an enclosure for electronic device;

FIG. 2 is similar to FIG. 1, but viewed from another aspect;

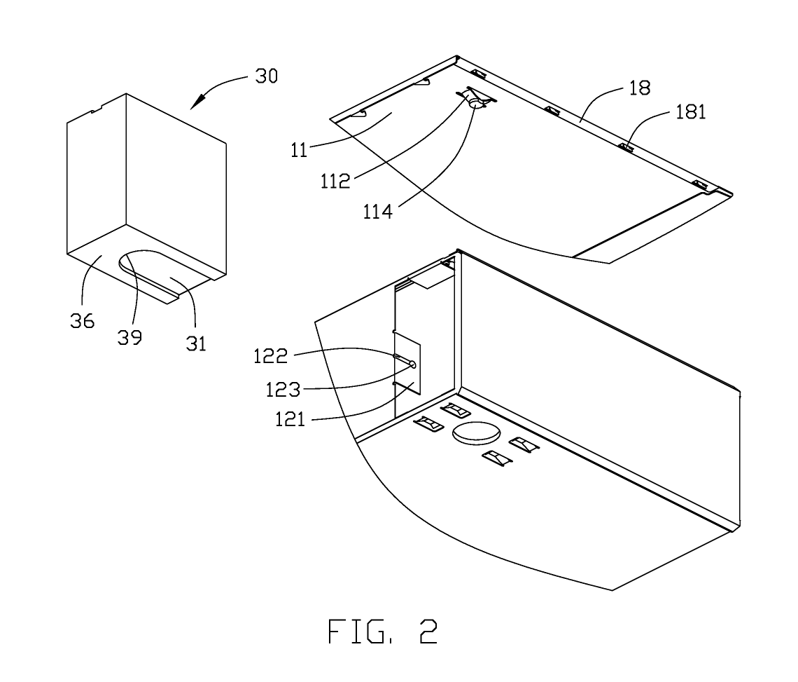

FIG. 3 is an partial-assembled view of the enclosure of FIG. 1; and

FIG. 4 is another partial-assembled view of the enclosure of FIG. 1.

### DETAILED DESCRIPTION

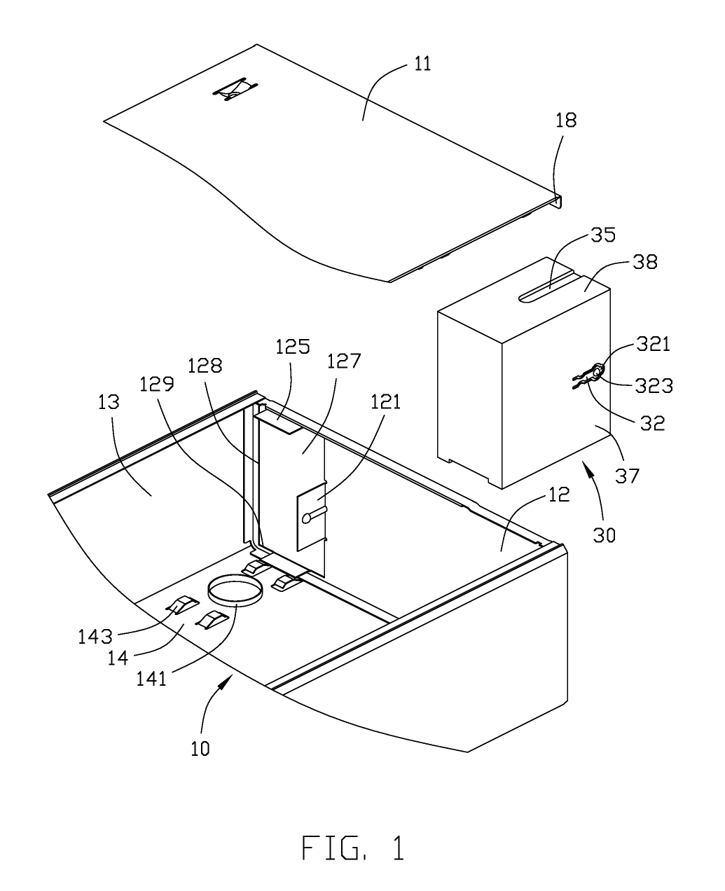

Referring to FIG. 1, an enclosure for mounting a power supply 30 in accordance with an exemplary embodiment is shown. The enclosure includes a chassis 10 and a cover 11. The chassis 10 includes a front wall 12, a sidewall 13, and a bottom wall 14. The bottom wall 14 is perpendicular to the front wall 12 and sidewall 13. The sidewall 13 is perpendicular to the front wall 12. The chassis 10 defines an uncovered side corresponding to the bottom wall 14. The cover 11 is mountable on the chassis 10 to cover the uncovered side.

The front wall 12 defines an opening 127. The opening 127 is designed to allow the power supply 30 inserted therethrough. The opening 127 has a pair of first edges 128 parallel to the sidewall 13, and a pair of second edges 129 perpendicular to the sidewall 13. One first edge 128 has a first restricting piece 121. The first restricting piece 121 is parallel with the sidewall 13. One side of the first restricting piece 121 defines a guiding slot 122 and a positioning recess 123. The recess 123 is deeper than the guiding slot 122. The guiding slot 122 extends from an edge of the opening 127 to the positioning recess 123. Each second edge 129 of the opening 127 extends in toward the chassis 10 to from a second restricting piece 125.

A ring 141 and a plurality of elastic pieces 143 protrude from the bottom wall 14. The plurality of elastic pieces 143 is located around the ring 141. Each elastic piece 143 has an end connected on the bottom wall 14, and another end protruding above the bottom wall 14.

The power supply 30 includes a bottom side 36, a right side 37, and a top side 38. The bottom side 36 of the power supply 30 defines a sliding groove 31. A width of the sliding groove 31 allows the ring 141 to receive the ring 141 sliding therein. One end of the sliding groove 31 is communicated with an edge of the power supply 30, and the other end of the sliding groove 31 is bounded by an arced edge 39 adapted to fit with the ring 141.

The right side 37 of the power supply 30 forms a tongue piece 32 thereon. The tongue piece 32 has an end connected on the power supply 30, and a free end 321 tilted away from the right side 37 of the power supply 30. A protrusion 323 is protruded on the free end 321 of tongue piece 32.

The top side 38 of the power supply 30 defines a receiving groove 35.

The cover 11 forms a bent piece 112. A block 114 is formed on the bent piece 112. An edge of the cover 11 is bent downwardly to form a flange 18. A plurality of clasps 181 is formed on the flange 18 for securing the cover 18 on the chassis 10.

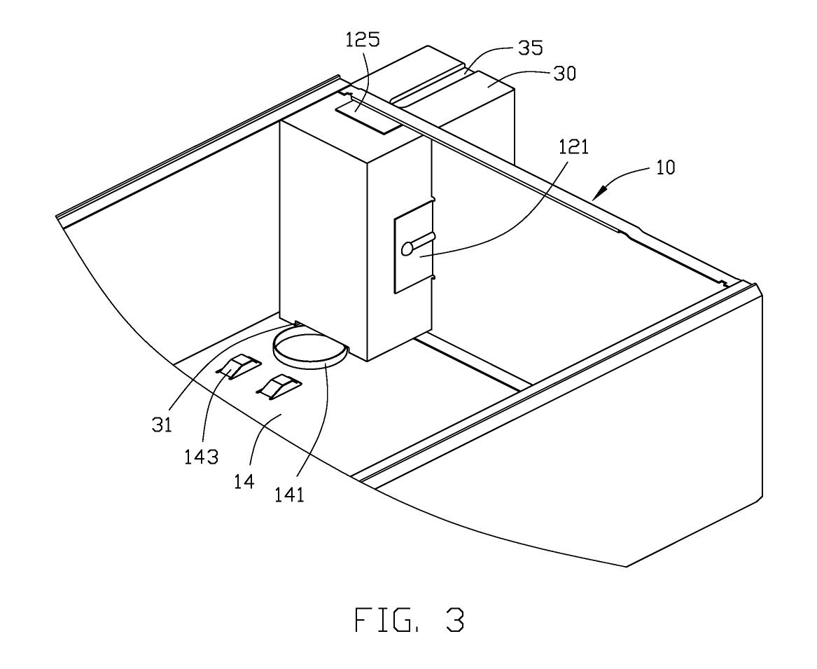

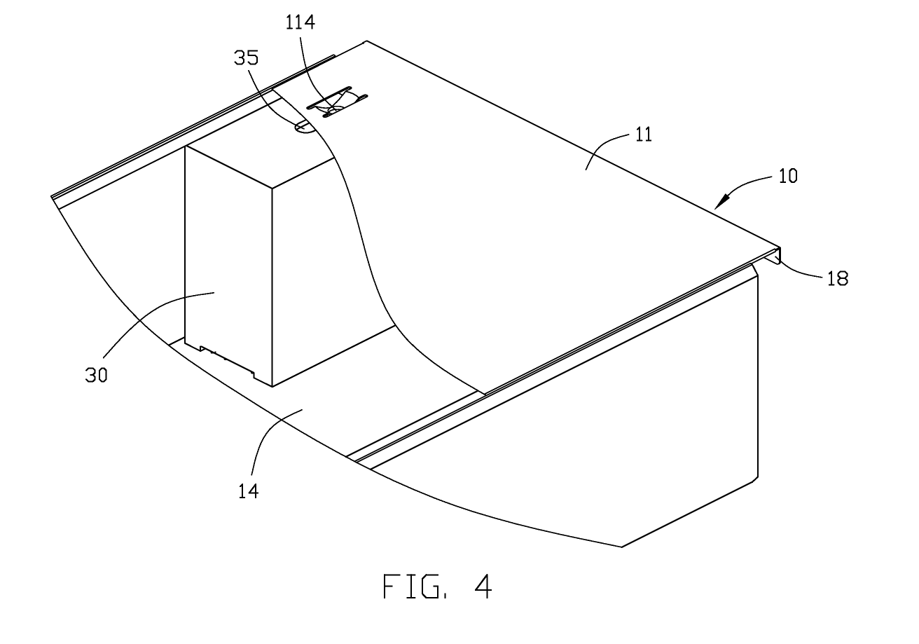

Referring to FIGS. 3 and 4, the power supply 30 is moved into the chassis 10 via the opening 127. The power supply 30 slides along the first restricting piece 121 and the second restricting pieces 125. The protrusion 323 of the power supply 30 slides into the guiding slot 122 of the first restricting piece 121, and the tongue piece 32 is elastically bent by the right side 37 of the power supply 30. Simultaneously, the sliding groove 31 of the power supply 30 receives the ring 141 sliding therein.

The power supply 30 slides into the chassis 10 until the ring 141 resists against the arced edge 39. Simultaneously, the protrusion 323 of the power supply 30 slides into the positioning recess 123 of the first restricting piece 121, and the tongue piece 32 rebounds. At this position, the power supply 30 is located on the plurality of elastic pieces 143.

Then, the cover 11 is attached to the chassis 10 with the block 114 positioned in the receiving groove 35 of the power supply 30. The block 114 of the cover 11 tightly presses the power supply 30 toward the elastic pieces 143. At last, the clasps 181 are locked on the chassis 10 to secure the cover 11 on the chassis 10. The power supply 30 is then firmly secured in the chassis 10.

It is to be understood, however, that even though numerous characteristics and advantages of the embodiments have been set forth in the foregoing description, together with details of the structure and function of the embodiments, the disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. An enclosure for electronic device, comprising:
a chassis comprising a bottom wall, a ring and a plurality of elastic pieces protruding from the bottom wall;
a power supply comprising a top side and bottom side, the bottom side defining a sliding groove, the top side defining a receiving groove, the power supply being located on the plurality of elastic pieces of the chassis with the ring positioned in the sliding groove; and
a cover comprising a protrusion, the cover being mounted on the chassis; the protrusion positioned in the receiving groove and biases the power supply toward the plurality of elastic pieces.

2. The enclosure of claim 1, wherein the chassis further comprises a front wall, the front wall defines an opening capable of allowing the power supply inserted therethrough.

3. The enclosure of claim 2, wherein one edge of the opening has a first restricting piece, a positioning recess is defined in the first restricting piece; the power supply comprises a right side, a tongue piece is formed on the right side of the power supply, the tongue piece comprises a titled free end, a protrusion is protruded on the free end of the tongue piece and is positioned in the positioning recess.

4. The enclosure of claim 3, wherein the first restricting piece has a guiding slot defined therein, and the guiding slot is capable of guiding the protrusion into the positioning recess.

5. The enclosure of claim 4, wherein the positioning recess is deeper than the guiding slot.

6. The enclosure of claim 1, wherein each elastic piece has an end connected on the bottom wall, and another end protruding above the bottom wall.

7. The enclosure of claim 1, wherein the plurality of elastic pieces is located around the ring.

8. The enclosure of claim 1, wherein one end of the sliding groove is in communication with an edge of the power supply, and the other end of the sliding groove is bounded by an arc edge corresponding to the ring.

9. An enclosure for electronic device, comprising:
a chassis comprising a front wall, the front wall defining an opening; an edge of the opening having a first restricting piece, a guiding slot and a positioning recess defined in the first restricting piece, the positioning recess being deeper than the guiding slot; and
a power supply being located in the chassis via the opening, a side of the power supply forming a tongue piece thereon, the tongue piece comprising a titled free end, a protrusion protruded on the free end of the tongue piece, the protrusion being positioned in the positioning recess via guided by the guiding slot to secure the power supply in the chassis.

10. The enclosure of claim 9, wherein the chassis comprises a bottom wall, a ring protrudes from the bottom wall, the power supply comprises a bottom side, a sliding groove is defined in the bottom side capable for receiving the ring sliding therein.

11. The enclosure of claim 10, wherein a plurality of elastic pieces protrude from the bottom wall, the power supply is located on the plurality of elastic pieces, the chassis comprises has uncovered side corresponding to the bottom wall, a cover is mounted on the chassis to cover the uncovered side of the chassis, and sandwiches the power supply between the cover and the plurality of elastic pieces.

12. The enclosure of claim 11, wherein each elastic piece has an end connected on the bottom wall, and another end protruding above the bottom wall.

13. The enclosure of claim 11, wherein the plurality of elastic piece is located around the ring.

14. The enclosure of claim 11, wherein the power supply comprises a top side, a receiving groove is defined in the top side, the cover comprises a protrusion received in the receiving groove and biasing the power supply toward the plurality of elastic pieces.

15. The enclosure of claim 10, where one end of the sliding groove is in communication with an edge of the power supply, and the other end of the sliding groove is bounded by an arc edge corresponding to the ring.
